(19) United States
(12) Patent Application Publication
(10) Pub. No.: US 2026/0113059 A1
(43) Pub. Date: Apr. 23, 2026

(54) DECODING APPARATUS AND METHOD IN WIRELESS COMMUNICATION NETWORK

(71) Applicant: Nokia Solutions and Networks Oy, Espoo (FI)

(72) Inventor: Jaakko Eino IImari Vihriälä, Oulu (FI)

(21) Appl. No.: 18/923,489

(22) Filed: Oct. 22, 2024

(51) Int. Cl. H03M 13/11; H03M 13/39

(52) U.S. Cl. CPC H03M 13/1111; H03M 13/3927

(57) ABSTRACT

A multi-stage decoding algorithm for improving the decoding performance of bits encoded with a linear error-correcting block code of small or medium block length is provided. The algorithm comprises an input stage, at least two intermediate stages and an output stage. For each of the stages (except for the last intermediate stage and the output stage), a certain number of bit positions is selected and set to a maximum possible absolute LLR value. The output data of each stage is used to compute the input data of the next stage. Each of the intermediate stages executes a specified number of parallel decoding runs, and the input data for each of the intermediate stages is generated based on the output data of the previous intermediate stage and initial LLRs obtained after demodulation. The bit positions set to the maximum possible absolute LLR value in the previous stage cannot be used again in the next stage. At the output stage, only one decoding run is executed, for which input data are formed based on the initial LLRs and the LLRs obtained at the last intermediate stage.

### TECHNICAL FIELD

The present disclosure relates generally to the field of wireless communications. In particular, the present disclosure relates to a decoding apparatus and method in a wireless communication network.

### BACKGROUND

A parity check is an error-correction process that is used to facilitate the recovery of data transmitted over a wireless communication channel. One type of parity check codes is a Low-Density Parity-Check (LDPC) code characterized by a Parity Check Matrix (PCM) representing a binary matrix that defines the connections between check nodes and variable nodes. An LDPC encoder on a transmitting side uses an LDPC coding scheme to encode a source word into a codeword, while a LDPC decoder on a receiving side uses the same LDPC coding scheme to decode the received codeword. Input data for the LDPC decoder may be represented by bit-wise Log-Likelihood Ratios (LLRs) from a demodulator. The LLRs contain reliability information of each bit decision made by the demodulator. At the output, the LDPC decoder may also provide LLRs for each bit (also parity bits).

As a rule, a message passing decoding algorithm is used for LDPC codes. Additionally, a Cyclic Redundancy Check (CRC) may be performed on the output of the LDPC decoder for the purpose of error detection. However, the message passing decoding algorithm has poor performance for small and medium-block length codes (e.g., those codes having up to 500 information bits). Although this drawback can be overcome by increasing the number of iterations in the message passing decoding algorithm, the resulting gain (in terms of low Block Error Rate (BLER) targets) remains very small.

### SUMMARY

This summary is provided to introduce a selection of concepts in a simplified form that are further described below in the detailed description. This summary is not intended to identify key features of the present disclosure, nor is it intended to be used to limit the scope of the present disclosure.

It is an objective of the present disclosure to provide a technical solution that improves the decoding performance of bits encoded with a linear error-correcting block code (e.g., LDPC code or polar code) of small or medium block length (e.g., including up to 500 information bits).

The objective above is achieved by the features of the independent claims in the appended claims. Further embodiments and examples are apparent from the dependent claims, the detailed description, and the accompanying drawings.

According to a first aspect, a decoding apparatus in a wireless communication network is provided. The decoding apparatus comprises at least one processor and at least one memory storing instructions that, when executed by the at least one processor, cause the decoding apparatus to perform at least as follows. At first, the decoding apparatus receives a modulated signal comprising a set of bits encoded with a linear error-correcting block code. Each bit of the set of bits has a bit position. Then, the decoding apparatus obtains a set of demodulated LLRs for the set of bits by demodulating the modulated signal. After that, the decoding apparatus decodes the set of bits by using a multi-stage decoding algorithm based on the set of demodulated LLRs. The multi-stage decoding algorithm comprises an input decoding stage, a first intermediate decoding stage, a second intermediate decoding stage and an output decoding stage.

At the input decoding stage, the decoding apparatus is caused to: (i) obtain a set of decoded LLRs based on the set of demodulated LLRs; (ii) find a first subset of B bit positions each associated with a first smallest absolute LLR value based on the set of decoded LLRs, where B is a natural number; (iii) instead of the first smallest absolute LLR value, assign a maximum possible absolute LLR value to each bit position of the first subset of B bit positions; and (iv) form first 2^{B} vectors of LLRs based on the set of demodulated LLRs, the set of decoded LLRs, and the first subset of B bit positions.

At the first intermediate stage, the decoding apparatus is caused to: (v) decode each of the first 2^{B} vectors of LLRs in parallel, thereby obtaining an individual set of decoded LLRs for each of the first 2^{B} vectors of LLRs; (vi) obtain a first averaged set of decoded LLRs by averaging the individual sets of decoded LLRs obtained in operation (v); (vii) find a second subset of B bit positions each associated with a second smallest absolute LLR value in the first averaged set of decoded LLRs, the second subset of B bit positions and the first subset of B bit positions being non-overlapping; (viii) instead of the second smallest absolute LLR value, assign the maximum possible absolute LLR value to each bit position of the second subset of B bit positions; and (ix) form second 2^{B} vectors of LLRs based on the set of demodulated LLRs, the first averaged set of decoded LLRs and the second subset of B bit positions.

At the second intermediate decoding stage, the decoding apparatus is caused to: (x) decode each of the second 2^{B} vectors of LLRs in parallel, thereby obtaining an individual set of decoded LLRs for each of the second 2^{B} vectors of LLRs; and (xi) obtain a second averaged set of decoded LLRs by averaging the individual sets of decoded LLRs obtained in operation (x).

Finally, at the output decoding stage, the decoding apparatus is caused to (xii) decode the set of bits based on the set of demodulated LLRs and the second averaged set of decoded LLRs.

The decoding apparatus thus configured may properly decode bits encoded, among others, with a linear error-correcting block code having a small or medium block length. This may make it possible to use the decoding apparatus in Ultra-Reliable Low Latency Communication (URLLC) and Machine-Type wireless Communication (MTC) applications where low BLERs are required, and packet sizes are smaller than in a mobile broadband.

In one example embodiment of the first aspect, the linear error-correcting block code is an LDPC code or a polar code, and the multi-stage decoding algorithm is an LDPC decoding algorithm or a polar code decoding algorithm, respectively. Polar and LDPC codes are two promising types of codes that may be efficiently used in 5G and next-generation communication systems. Therefore, the decoding apparatus configured to perform LDPC or polar decoding may be efficiently used in the upcoming next-generation communication systems.

In one example embodiment of the first aspect, the LDPC decoding algorithm is a min-sum LDPC decoding algorithm or a sum-product LDPC decoding algorithm. This may allow the decoding apparatus to be more flexible in use.

In one example embodiment of the first aspect, the decoding apparatus is further caused, in operation (ix), to calculate a weighted sum of the set of demodulated LLRs and the first averaged set of decoded LLRs and to form the second 2^{B} vectors of LLRs based on the weighted sum of the set of demodulated LLRs and the first averaged set of decoded LLRs. By doing so, it is possible to increase the BLER-related efficiency of the multi-stage decoding algorithm.

In one example embodiment of the first aspect, the linear error-correcting block code has a block length and a code rate, and the decoding apparatus is further caused to calculate the weighted sum of the set of demodulated LLRs and the first averaged set of decoded LLRs taking into account the block length and the code rate. By doing so, it is possible to perform said weighted-sum calculation more efficiently, thereby further improving the BLER-related efficiency of the multi-stage decoding algorithm.

In one example embodiment of the first aspect, the decoding apparatus is caused, in operations (i), (vi) and (x), to check whether there is at least one bit error in the set of decoded LLRs, the first averaged set of decoded LLRs and the second averaged set of decoded LLRs, respectively, by using a CRC technique. By doing so, it is possible to detect accidental changes or errors in the set of bits transmitted by using the modulated signal in the wireless communication network.

According to a second aspect, a decoding method in a wireless communication network is provided. The method starts with the step of receiving a modulated signal comprising a set of bits encoded with a linear error-correcting block code. Each bit of the set of bits has a bit position. Next, the method goes on to the step of obtaining a set of demodulated LLRs for the set of bits by demodulating the modulated signal. After that, the method proceeds to the step of decoding the set of bits by using a multi-stage decoding algorithm based on the set of demodulated LLRs. The multi-stage decoding algorithm comprises an input decoding stage, a first intermediate decoding stage, a second intermediate decoding stage and an output decoding stage.

The input decoding stage comprises: (i) obtaining a set of decoded LLRs based on the set of demodulated LLRs; (ii) finding a first subset of B bit positions each associated with a first smallest absolute LLR value in the set of decoded LLRs, where B is a natural number; (iii) instead of the first smallest absolute LLR value, assigning a maximum possible absolute LLR value to each bit position of the first subset of B bit positions; and (iv) forming first 2^{B} vectors of LLRs based on the set of demodulated LLRs, the set of decoded LLRs, and the first subset of B bit positions.

The first intermediate decoding stage comprises: (v) decoding each of the first 2^{B} vectors of LLRs in parallel, thereby obtaining an individual set of decoded LLRs for each of the first 2^{B} input vectors; (vi) obtaining a first averaged set of decoded LLRs by averaging the individual sets of decoded LLRs obtained in step (v); (vii) finding a second subset of B bit positions each associated with a second smallest absolute LLR value in the first averaged set of decoded LLRs, the second subset of B bit positions and the first subset of B bit positions being non-overlapping; (viii) instead of the second smallest absolute LLR value, assigning the maximum possible absolute LLR value to each bit position of the second subset of B bit positions; and (ix) forming second 2^{B} vectors of LLRs based on the set of demodulated LLRs, the first averaged set of decoded LLRs and the second subset of B bit positions.

The second intermediate decoding stage comprises: (x) decoding each of the second 2^{B} vectors of LLRs in parallel, thereby obtaining an individual set of decoded LLRs for each of the second 2^{B} vectors of LLRs; and (xi) obtaining a second averaged set of decoded LLRs by averaging the individual sets of decoded LLRs obtained in step (x).

Finally, the output decoding stage comprises (xii) decoding the set of bits based on the set of demodulated LLRs and the second averaged set of decoded LLRs.

By using the decoding method according to the second aspect, it is possible to properly decode bits encoded, among others, with a linear error-correcting block code having a small or medium block length. This may make it possible to use the decoding method in the URLLC and MTC applications where low BLERs are required, and packet sizes are smaller than in a mobile broadband.

In one example embodiment of the second aspect, the linear error-correcting block code is an LDPC code or a polar code, and the multi-stage decoding algorithm is an LDPC decoding algorithm or a polar code decoding algorithm, respectively. Polar and LDPC codes are two promising types of codes that may be efficiently used in 5G and next-generation communication systems. Therefore, the decoding method according to the second aspect may be efficiently used in the upcoming next-generation communication systems.

In one example embodiment of the second aspect, the LDPC decoding algorithm is a min-sum LDPC decoding algorithm or a sum-product LDPC decoding algorithm. This may allow the decoding method according to the second aspect to be more flexible in use.

In one example embodiment of the second aspect, step (ix) is performed by calculating a weighted sum of the set of demodulated LLRs and the first averaged set of decoded LLRs and forming the second 2^{B} vectors of LLRs based on the weighted sum of the set of demodulated LLRs and the first averaged set of decoded LLRs. By doing so, it is possible to increase the BLER-related efficiency of the multi-stage decoding algorithm.

In one example embodiment of the second aspect, the linear error-correcting block code has a block length and a code rate, and the weighted sum of the set of demodulated LLRs and the first averaged set of decoded LLRs is calculated taking into account the block length and the code rate. By doing so, it is possible to perform said weighted-sum calculation more efficiently, thereby further improving the BLER-related efficiency of the multi-stage decoding algorithm.

In one example embodiment of the second aspect, the decoding method further comprises, in each of steps (i), (vi) and (x), the sub-step of checking whether there is at least one bit error in the set of decoded LLRs, the first averaged set of decoded LLRs and the second averaged set of decoded LLRs, respectively, by using a CRC technique. By doing so, it is possible to detect accidental changes or errors in the set of bits transmitted by using the modulated signal in the wireless communication network.

According to a third aspect, a computer program product is provided. The computer program product comprises a computer-readable storage medium that stores a computer code. Being executed by at least one processor, the computer code causes the at least one processor to perform the method according to the second aspect. By using such a computer program product, it is possible to simplify the implementation of the method according to the second aspect in any decoding apparatus, like the decoding apparatus according to the first aspect.

According to a fourth aspect, a decoding apparatus in a wireless communication network is provided. The decoding apparatus comprises a means for receiving a modulated signal comprising a set of bits encoded with a linear error-correcting block code. Each bit of the set of bits has a bit position. The decoding apparatus further comprises a means for obtaining a set of demodulated LLRs for the set of bits by demodulating the modulated signal. The decoding apparatus further comprises a means for decoding the set of bits by using a multi-stage decoding algorithm based on the set of demodulated LLRs. The multi-stage decoding algorithm comprises an input decoding stage, a first intermediate decoding stage, a second intermediate decoding stage and an output decoding stage.

At the input decoding stage, the decoding means is configured to: (i) obtain a set of decoded LLRs based on the set of demodulated LLRs; (ii) find a first subset of B bit positions each associated with a first smallest absolute LLR value in the set of decoded LLRs, where B is a natural number; (iii) instead of the first smallest absolute LLR value, assign a maximum possible absolute LLR value to each bit position of the first subset of B bit positions; and (iv) form first 2^{B} vectors of LLRs based on the set of demodulated LLRs, the set of decoded LLRs and the first subset of B bit positions.

At the first intermediate stage, the decoding means is configured to: (v) decode each of the first 2^{B} vectors of LLRs in parallel, thereby obtaining an individual set of decoded LLRs for each of the first 2^{B} vectors of LLRs; (vi) obtain a first averaged set of decoded LLRs by averaging the individual sets of decoded LLRs obtained in operation (v); (vii) find a second subset of B bit positions each associated with a second smallest absolute LLR value in the first averaged set of decoded LLRs, the second subset of B bit positions and the first subset of B bit positions being non-overlapping; (viii) instead of the second smallest absolute LLR value, assign the maximum possible absolute LLR value to each bit position of the second subset of B bit positions; and (ix) form second 2^{B} vectors of LLRs based on the set of demodulated LLRs, the first averaged set of decoded LLRs and the second subset of B bit positions.

At the second intermediate decoding stage, the decoding means is configured to: (x) decode each of the second 2^{B} vectors of LLRs in parallel, thereby obtaining an individual set of decoded LLRs for each of the second 2^{B} vectors of LLRs; and (xi) obtain a second averaged set of decoded LLRs by averaging the individual sets of decoded LLRs obtained in operation (x).

Finally, at the output decoding stage, the decoding means is configured to (xii) decode the set of bits based on the set of demodulated LLRs and the second averaged set of decoded LLRs.

The decoding apparatus thus configured may properly decode bits encoded, among others, with a linear error-correcting block code having a small or medium block length. This may make it possible to use the decoding apparatus in the URLLC and MTC applications where low BLERs are required, and packet sizes are smaller than in a mobile broadband.

Other features and advantages of the present disclosure will be apparent upon reading the following detailed description and reviewing the accompanying drawings.

### BRIEF DESCRIPTION OF THE DRAWINGS

The present disclosure is explained below with reference to the accompanying drawings in which:

FIG. 1 shows a block diagram of an LDPC decoder in accordance with the prior art;

FIGS. 2A-2D schematically explain how the LDPC decoder of FIG. 1 may perform saturation with respect to the least reliable bit positions (i.e., those bit positions corresponding to the smallest absolute LLR value);

FIG. 3 shows a block diagram of a decoding apparatus in accordance with one example embodiment;

FIG. 4 shows a flowchart of a method for operating the apparatus of FIG. 3 in accordance with one example embodiment;

FIG. 5 shows a sub-step sequence of an input decoding stage of a multi-stage decoding algorithm used in the method of FIG. 4 in accordance with one example embodiment;

FIG. 6 shows a sub-step sequence of a first intermediate decoding stage of the multi-stage decoding algorithm used in the method of FIG. 4 in accordance with one example embodiment;

FIG. 7 shows a sub-step sequence of a second intermediate decoding stage of the multi-stage decoding algorithm used in the method of FIG. 4 in accordance with one example embodiment;

FIG. 8 shows a block diagram of a processor included in the apparatus of FIG. 3 in accordance with one example embodiment; and

FIGS. 9A and 9B show a BLER versus a Signal-to-Noise Ratio (SNR), as obtained by using a conventional decoding method and the method of FIG. 4 for two different LDPC codes, namely: the curves shown in FIG. 9A are obtained for the LDPC code having K=44 information bits and a code rate of R=1/3, while the curves shown in FIG. 9B are obtained for the LDPC code having K=88 information bits and a code rate of R=1/3.

### DETAILED DESCRIPTION

Various embodiments of the present disclosure are further described in more detail with reference to the accompanying drawings. However, the present disclosure can be embodied in many other forms and should not be construed as limited to any certain structure or function discussed in the following description. In contrast, these embodiments are provided to make the description of the present disclosure detailed and complete.

According to the detailed description, it will be apparent to the ones skilled in the art that the scope of the present disclosure encompasses any embodiment thereof, which is disclosed herein, irrespective of whether this embodiment is implemented independently or in concert with any other embodiment of the present disclosure. For example, the apparatus and method disclosed herein can be implemented in practice by using any numbers of the embodiments provided herein. Furthermore, it should be understood that any embodiment of the present disclosure can be implemented using one or more of the elements presented in the appended claims.

Unless otherwise stated, any embodiment recited herein as “example embodiment” should not be construed as preferable or having an advantage over other embodiments.

According to the example embodiments disclosed herein, a User Equipment (UE) may refer to an electronic computing device that is configured to perform wireless communications. The UE may be implemented as a mobile station, a mobile terminal, a mobile subscriber unit, a mobile phone, a cellular phone, a smart phone, a cordless phone, a personal digital assistant (PDA), a wireless communication device, a desktop computer, a laptop computer, a tablet computer, a gaming device, a netbook, a smartbook, an ultrabook, a medical mobile device or equipment, a biometric sensor, a wearable device (e.g., a smart watch, smart glasses, a smart wrist band, etc.), an entertainment device (e.g., an audio player, a video player, etc.), a vehicular component or sensor (e.g., a driver-assistance system), a smart meter/sensor, an unmanned vehicle (e.g., an industrial robot, a quadcopter, etc.) and its component (e.g., a self-driving car computer), industrial manufacturing equipment, a global positioning system (GPS) device, an Internet-of-Things (IoT) device, an Industrial IoT (IIoT) device, a machine-type communication (MTC) device, a group of Massive IoT (MIoT) or Massive MTC (mMTC) devices/sensors, or any other suitable mobile device configured to support wireless communications. In some embodiments, the UE may refer to at least two collocated and inter-connected UEs thus defined.

As used in the example embodiments disclosed herein, a network node may refer to a fixed point of communication/communication node for a UE in a particular wireless communication network. More specifically, the network node may be used to connect the UE to a Data Network (DN) through a Core Network (CN) and may be referred to as a base transceiver station (BTS) in terms of the 2G communication technology, a NodeB in terms of the 3G communication technology, an evolved NodeB (eNodeB or eNB) in terms of the 4G communication technology, and a gNB or relay station (e.g., Integrated Access and Backhaul (IAB)) in terms of the 5G or 6G New Radio (NR) communication technology. The network node may serve different cells, such as a macrocell, a microcell, a picocell, a femtocell, and/or other types of cells. The macrocell may cover a relatively large geographic area (e.g., at least several kilometers in radius). The microcell may cover a geographic area less than two kilometers in radius, for example. The picocell may cover a relatively small geographic area, such, for example, as offices, shopping malls, train stations, stock exchanges, etc. The femtocell may cover an even smaller geographic area (e.g., a home). Correspondingly, the network node serving the macrocell may be referred to as a macro node, the network node serving the microcell may be referred to as a micro node, and so on.

According to the example embodiments disclosed herein, a wireless communication network, in which a UE and a network node communicate with each other, may refer to a cellular or mobile network, a Wireless Local Area Network (WLAN), a Wireless Personal Area Networks (WPAN), a Wireless Wide Area Network (WWAN), a satellite communication (SATCOM) system, or any other type of wireless communication networks. Each of these types of wireless communication networks supports wireless communications according to one or more communication protocol standards. For example, the cellular network may operate according to the Global System for Mobile Communications (GSM) standard, the Code-Division Multiple Access (CDMA) standard, the Wide-Band Code-Division Multiple Access (WCDM) standard, the Time-Division Multiple Access (TDMA) standard, or any other communication protocol standard, the WLAN may operate according to one or more versions of the IEEE 802.11 standards, the WPAN may operate according to the Infrared Data Association (IrDA), Wireless USB, Bluetooth, or ZigBee standard, and the WWAN may operate according to the Worldwide Interoperability for Microwave Access (WiMAX) standard.

Block codes, or error correcting codes, are frequently used to provide reliable transmission of data over noisy wireless communication channels. In a typical block code, an information message or sequence is split up into blocks, and an encoder at a transmitting device then mathematically adds redundancy to the information message. Exploitation of this redundancy in the encoded information message is the key to reliability of the message, enabling correction for any bit errors that may occur due to noise. That is, a decoder at a receiving device can take advantage of the redundancy to reliably recover the information message even though bit errors may occur, in part, due to the addition of noise to the wireless communication channel.

One example of such block codes is LDPC codes which are well-known to those skilled in the art. For future networks, such as 6G networks, the LDPC codes may continue to be implemented to support a wide range of information block lengths and a wide range of code rates.

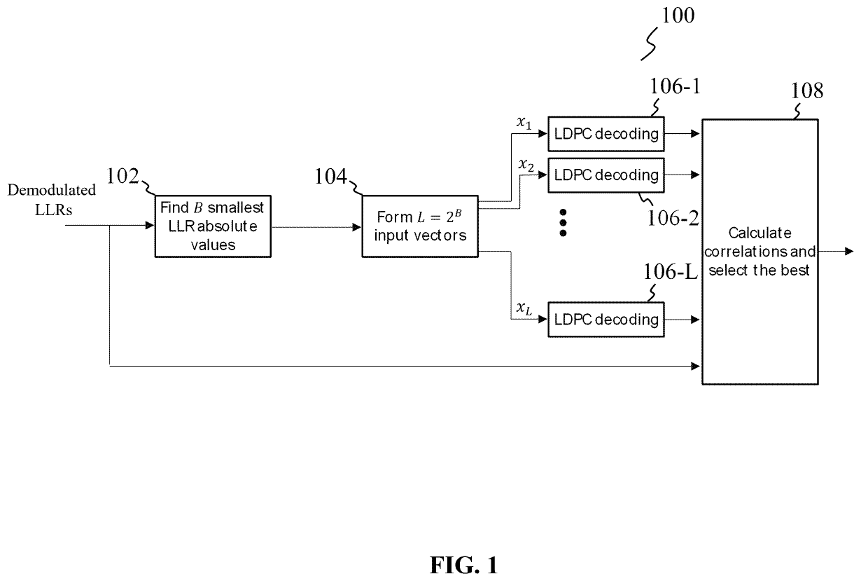

FIG. 1 shows a block diagram of an LDPC decoder 100 in accordance with the prior art. More specifically, the LDPC decoder 100 corresponds to the one disclosed in the following document: P. Schlaefer, S. Scholl, E. Leonardi, and N. Wehn, “A new LDPC decoder hardware implementation with improved error rates,” in 2015 IEEE Jordan Conference on Applied Electrical Engineering and Computing Technologies (AEECT), 2015, pp. 1-6. The LDPC decoder 100 may be part of a receiver included in a UE or a network node and is configured to implement the so-called saturated decoding as follows.

Let us consider the transmission of N code bits x=(x₀, x₁, . . . , x_{N-1}) over an Additive White Gaussian Noise (AWGN) channel using Binary Phase-Shift Keying (BPSK) and 64-Quadrature Amplitude Modulation (QAM) modulation. On the receiver side, the received code bits are described by a set of LLRs y=(y, y₁, . . . , y_{N-1}) obtained by means of demodulation, where

$${y}_{i} = ln ( \frac{p ( {x}_{i} = 0 )}{p ( {x}_{i} = 1 )} ) ∈ ℝ ,$$

where p (xᵢ=0) represents the probability that the i-th code bit of x is a binary value of 0, p (xᵢ=1) represents the probability that the i-th code bit of x is a binary value of 1, and [symbol] is the field of real numbers. The value |yᵢ| can be considered as a measure of reliability of the received code bits. A small value |yᵢ| corresponds to an unreliable bit that is more likely in error than others.

Referring to FIG. 1, the LDPC decoder 100 comprises a unit 102 which is configured to receive the set y of demodulated LLRs. As noted above, all LLRs are real numbers. The unit 102 is further configured to find B smallest LLR values for saturation prior to starting the decoding process itself. This is done by sorting the values |yᵢ| and selecting the smallest one among them. In other words, the unit 102 determines bit positions which correspond to the smallest absolute value |yᵢ|. After that, L=2^{B} input vectors of LLRs are generated in a next unit 104 of the LDPC decoder 100 by setting the least reliable bit positions to a maximum possible absolute LLR value, i.e., they are saturated. Next, for each of the L input vectors of LLRs, a decoding run is executed in corresponding one of LDPC decoding units 106-1, 106-2, . . . , 106-L which included in the LDPC decoder 100. Finally, the output data (codewords) of the LDPC decoding units 106-1, 106-2, . . . , 106-L are compared in a unit 108 of the LDPC decoder 100 to find any correlation, and the best codeword is selected.

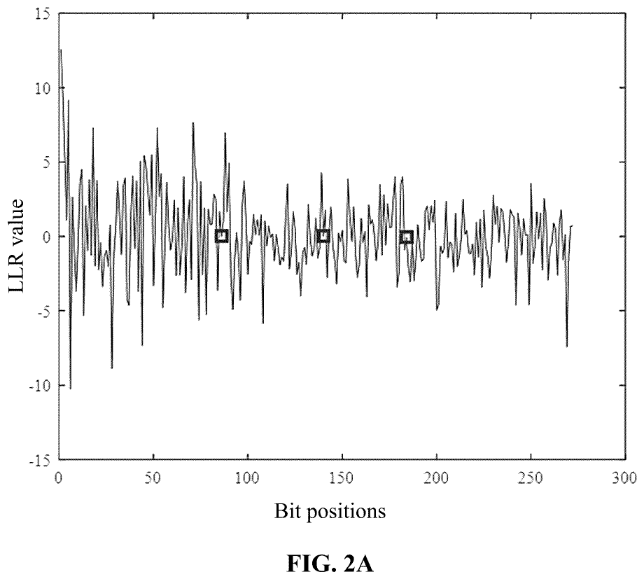

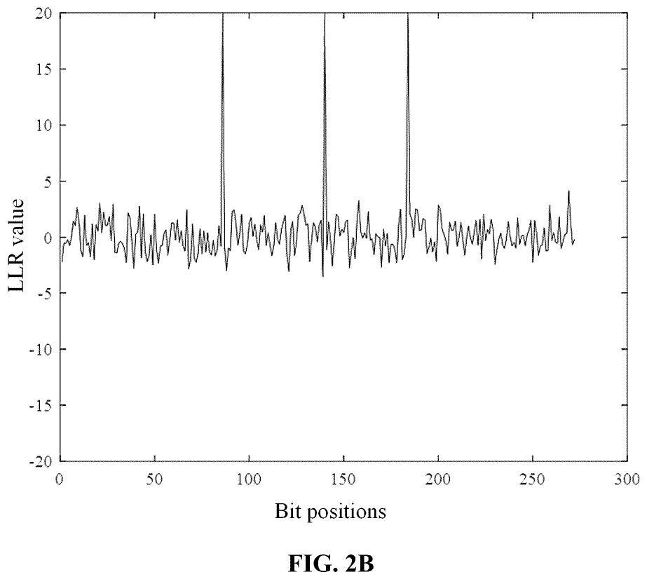

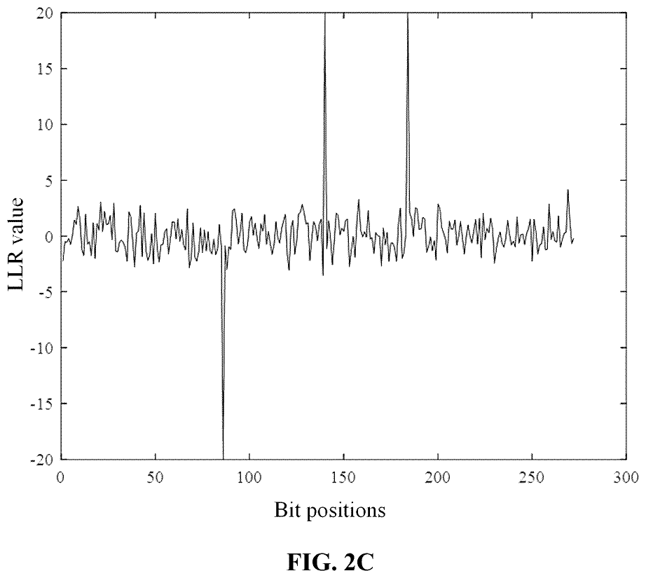

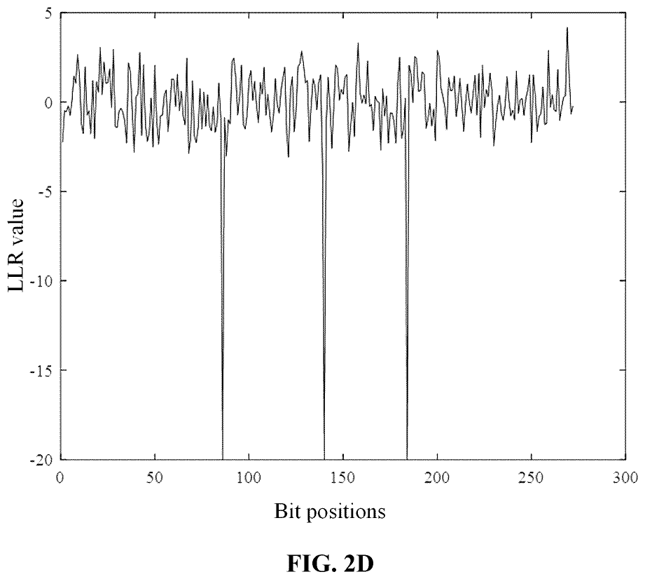

FIGS. 2A-2D schematically explain how the LDPC decoder 100 may perform the above-mentioned saturation with respect to the least reliable bit positions (i.e., those bit positions corresponding to the smallest absolute LLR value). In FIG. 2A, it is assumed that the set y of demodulated LLRs comprises three bit positions corresponding to the smallest LLR value, i.e., B=3 (these three bit positions are shown as black squares in FIG. 2A). Each of the three bit positions should be assigned a maximum possible absolute LLR value, i.e., plus infinity (+inf) and minus infinity (−inf) in the ideal case. In practice, these infinity values can, of course, be replaced by the LLR values that are big/small enough compared to the other LLR values (e.g., such big/small LLR values may be defined based on capabilities of the LDPC decoder 100). Given this, one can obtain L=2\hat{ }3=8 different sets y of demodulated LLRs, in each of which there are three saturated bit positions. For example, FIG. 2B relates to the set y of demodulated LLRs, in which the three bit positions are all saturated by assigning each of them a maximum positive LLR value. FIG. 2C relates to the set y of demodulated LLRs, in which two of the bit positions are saturated by assigning them the maximum positive LLR value and one of the bit positions is saturated by assigning it a maximum negative LLR value. FIG. 2D relates to the set y of demodulated LLRs, in which the three bit positions are all saturated by assigning each of them the maximum negative LLR value. Those skilled in the art would recognize how to obtain the rest of said 8 different sets y of demodulated LLRs. Each of said 8 different sets y of demodulated LLRs is processed by corresponding one of the LDPC decoding units 106-1, 106-2, . . . , 106-L. In other words, the LDPC decoding unit 106-1 processes the set y of demodulated LLRs which is shown in FIG. 2B, the LDPC decoding unit 106-2 processes the set y of demodulated LLRs which is shown in FIG. 2C, and so on—the last LDPC decoding unit 106-L process the set y of demodulated LLRs which is shown in FIG. 2D.

The above-described operation of the LDPC decoder 100 improves the probability of correct decoding but at the cost of increased complexity.

The example embodiments disclosed herein provide a technical solution that allows mitigating or even eliminating the above-sounded drawbacks peculiar to the prior art. In particular, the technical solution disclosed herein improves the decoding performance of bits encoded with a linear error-correcting block code (e.g., LDPC code or polar code) of small or medium block length (i.e., up to 500 information bits). For this purpose, a multi-stage decoding algorithm is used, which comprises an input decoding stage, at least two intermediate decoding stages and an output decoding stage. For each of the decoding stages (except for the last intermediate decoding stage and the output decoding stage), a certain number of bit positions is selected and set to a maximum possible absolute LLR value. The output data of each decoding stage is used to compute the input data of the next decoding stage. Each of the intermediate decoding stages executes a specified number of parallel decoding runs, and the input data for each of the intermediate decoding stages may be generated based on the output data of the previous intermediate decoding stage and initial LLRs obtained after demodulation. The bit positions set to the maximum possible absolute LLR value in the previous decoding stage cannot be used again in the next decoding stage. At the output decoding stage, only one decoding run is executed, for which input data are formed based on the initial LLRs and the LLRs obtained at the last intermediate decoding stage.

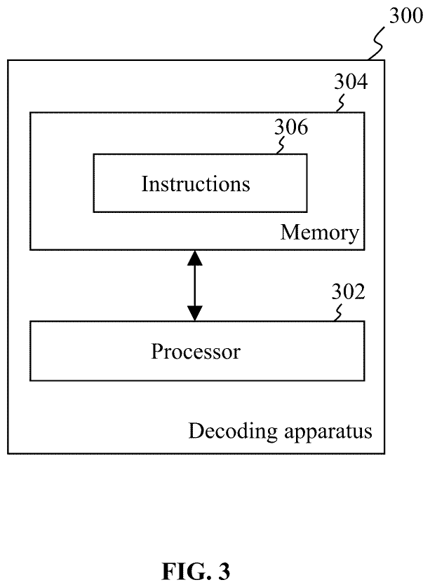

FIG. 3 shows a block diagram of a decoding apparatus 300 in accordance with one example embodiment. The decoding apparatus 300 is intended to be part of a receiver included in a UE or a network node in a wireless communication network. As shown in FIG. 3, the decoding apparatus 300 comprises a processor 302 and a memory 304. The memory 304 stores processor-executable instructions 306 which, when executed by the processor 302, cause the processor 302 to perform the aspects of the present disclosure, as will be described below in more detail. It should be noted that the number, arrangement, and interconnection of the constructive elements constituting the decoding apparatus 300, which are shown in FIG. 3, are not intended to be any limitation of the present disclosure, but merely used to provide a general idea of how the constructive elements may be implemented within the decoding apparatus 300. For example, the processor 302 may be replaced with several processors, as well as the memory 304 may be replaced with several removable and/or fixed storage devices, depending on particular applications. Furthermore, it is assumed that the processor 302 is capable of performing different operations required to perform data reception and transmission, such, for example, as signal modulation/demodulation, encoding/decoding, etc.

The processor 302 may be implemented as a CPU, general-purpose processor, single-purpose processor, microcontroller, microprocessor, application specific integrated circuit (ASIC), field programmable gate array (FPGA), digital signal processor (DSP), complex programmable logic device, etc. It should be also noted that the processor 302 may be implemented as any combination of one or more of the aforesaid. As an example, the processor 302 may be a combination of two or more microprocessors.

The memory 304 may be implemented as a classical nonvolatile or volatile memory used in the modern electronic computing machines. As an example, the nonvolatile memory may include Read-Only Memory (ROM), ferroelectric Random-Access Memory (RAM), Programmable ROM (PROM), Electrically Erasable PROM (EEPROM), solid state drive (SSD), flash memory, magnetic disk storage (such as hard drives and magnetic tapes), optical disc storage (such as CD, DVD and Blu-ray discs), etc. As for the volatile memory, examples thereof include Dynamic RAM, Synchronous DRAM (SDRAM), Double Data Rate SDRAM (DDR SDRAM), Static RAM, etc.

The processor-executable instructions 306 stored in the memory 304 may be configured as a computer-executable program code which causes the processor 302 to perform the aspects of the present disclosure. The computer-executable program code for carrying out operations or steps for the aspects of the present disclosure may be written in any combination of one or more programming languages, such as Java, C++, or the like. In some examples, the computer-executable program code may be in the form of a high-level language or in a pre-compiled form and be generated by an interpreter (also pre-stored in the memory 304) on the fly.

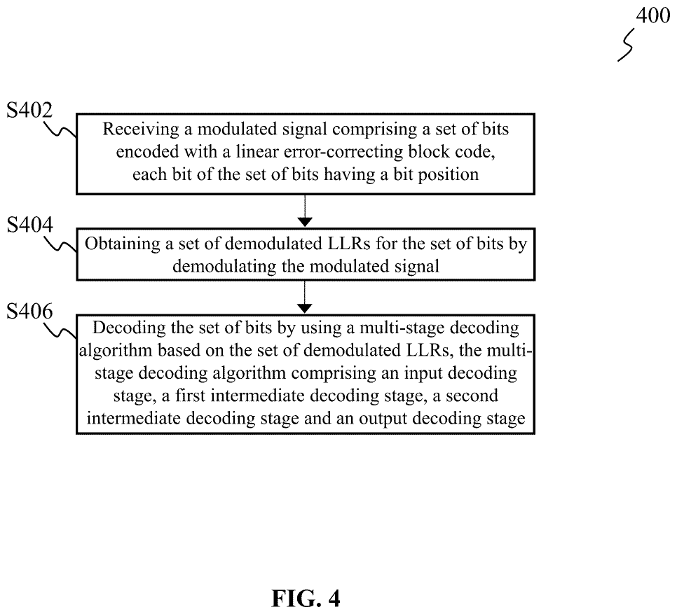

FIG. 4 shows a flowchart of a method 400 for operating the decoding apparatus 300 in accordance with one example embodiment. The method 400 starts with a step S402, in which the processor 302 receives a modulated signal comprising a set of bits encoded with a linear error-correcting block code (e.g., LDPC code or polar code). Each bit of the set of bits has a bit position. Next, the method 400 goes on to a step S404, in which the processor 302 obtains a set of demodulated LLRs for the set of bits by demodulating the modulated signal. After that, the method 400 proceeds to a step S406, in which the processor 302 decodes the set of bits by using a multi-stage decoding algorithm based on the set of demodulated LLRs. The multi-stage decoding algorithm comprises an input decoding stage, a first intermediate decoding stage, a second intermediate decoding stage and an output decoding stage. It should be noted that the number of intermediate decoding stages may be more than two, if required and depending on particular applications. For example, the number of the intermediate decoding stages may depend on a code rate, a number of information bits per a code block, etc. Each of the decoding stages of the multi-stage decoding algorithm will be now described in more detail with reference to the figures.

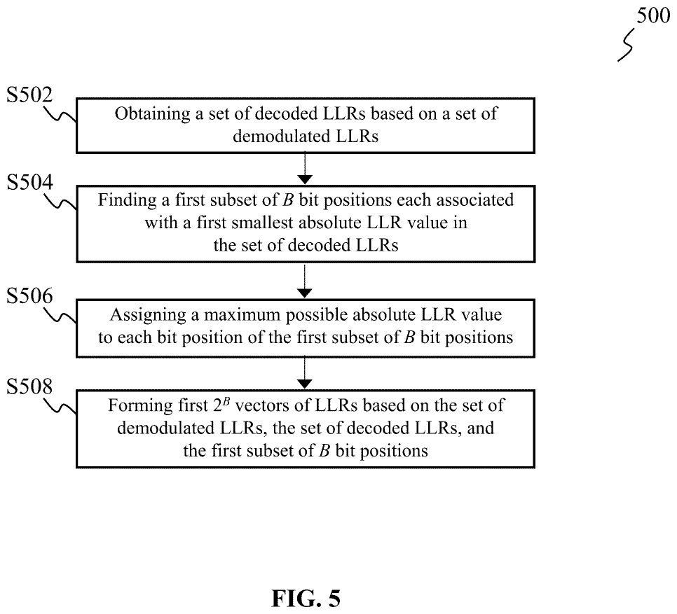

FIG. 5 shows a sub-step sequence 500 of the input decoding stage of the multi-stage decoding algorithm used in the method 400 in accordance with one example embodiment. As shown, the sub-step sequence 500 comprises sub-steps S502-S508. In the sub-step S502, the processor 302 obtains a set of decoded LLRs based on the set of demodulated LLRs. In the sub-step S504, the processor 302 finds a first subset of B bit positions each associated with a first smallest absolute LLR value in the set of decoded LLRs, where B is a natural number. In the sub-step S506, the processor 302 assigns a maximum possible absolute LLR value to each bit position of the first subset of B bit positions, i.e., the processor 302 performs the above-described saturation. In the sub-step S508, the processor 302 forms first 2^{B} vectors of LLRs based on the set of demodulated LLRs, the set of decoded LLRs, and the first subset of B bit positions. The processor 202 may perform said saturation and form the first 2^{B} vectors of LLRs in the same or similar manner as discussed above with references to FIGS. 2A-2D. The maximum possible absolute LLR value used in the sub-step S506 refers to a value |LLR| such that −LLR<<yᵢ<<+LLR, where yᵢ is the i-th LLR value from the set of decoded LLRs obtained in the sub-step S502.

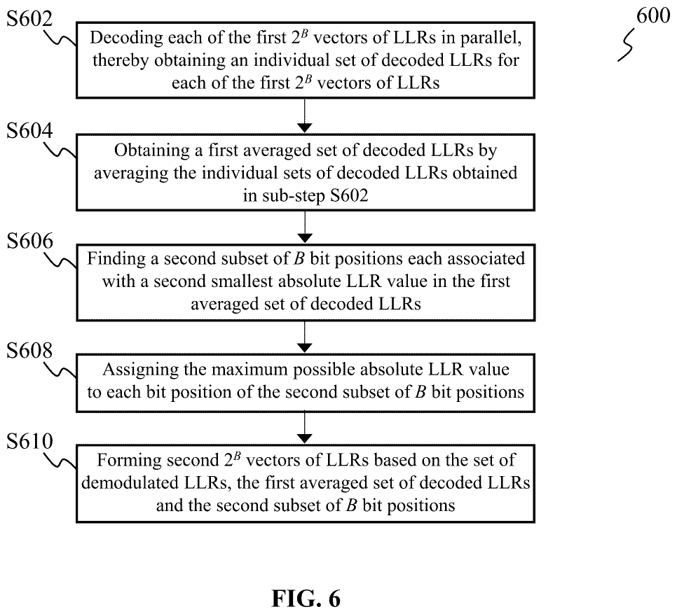

FIG. 6 shows a sub-step sequence 600 of the first intermediate decoding stage of the multi-stage decoding algorithm used in the method 400 in accordance with one example embodiment. As shown, the sub-step sequence 600 comprises sub-steps S602-S610. In the sub-step S602, the processor 202 initiates a decoding run for each of the first 2^{B} vectors of LLRs in parallel, thereby obtaining an individual set of decoded LLRs for each of the first 2^{B} vectors of LLRs. In the sub-step S604, the processor 302 obtains a first averaged set of decoded LLRs by averaging the individual sets of decoded LLRs obtained in the sub-step S602. In the sub-step S606, the processor 302 finds a second subset of B bit positions in the first averaged set of decoded LLRs. The second subset of B bit positions found by the processor 302 in the sub-step S606 does not overlap with the first subset of B bit positions found by the processor 302 in the sub-step S504 during the input decoding stage. In the sub-step S608, the processor 302 assigns the maximum possible absolute LLR value to each bit position of the second subset of B bit positions. In this case, the same maximum possible absolute LLR value is used as the one in the sub-step S506, i.e., −LLR<<yᵢ<+LLR, but yᵢ is now the i-th LLR value from the first averaged set of decoded LLRs obtained in the sub-step S604. In the sub-step S610, the processor 302 forms second 2^{B} vectors of LLRs based on the set of demodulated LLRs, the first averaged set of decoded LLRs and the second subset of bit positions. Again, the sub-steps S608 and S610 may be performed in the same or similar manner as discussed above with reference to FIGS. 2A-2D. In one embodiment, the processor 302 may use the weighted sum of the set of demodulated LLRs and the first averaged set of decoded LLRs in the sub-step S610 (for example, said weighted sum may be calculated taking into account the block length and code rate of the linear error-correcting block code).

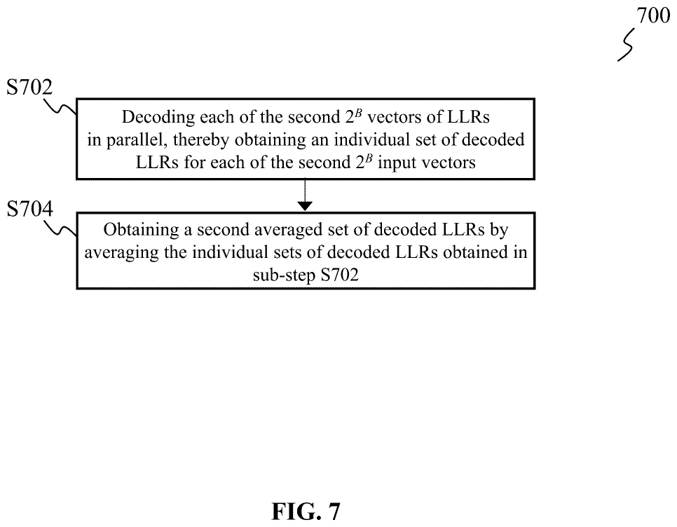

FIG. 7 shows a sub-step sequence 700 of the second intermediate decoding stage of the multi-stage decoding algorithm used in the method 400 in accordance with one example embodiment. As shown, the sub-step sequence 700 comprises sub-steps S702 and S704. In the sub-step S702, the processor 302 decodes each of the second 2^{B} vectors of LLRs in parallel, thereby obtaining an individual set of decoded LLRs for each of the second 2^{B} vectors of LLRs. In the sub-step S704, the processor 302 obtains a second averaged set of decoded LLRs by averaging the individual sets of decoded LLRs obtained in the sub-step S702.

The output decoding stage of the multi-stage decoding algorithm implies that the processor 302 decodes the set of bits based on the set of demodulated LLRs and the second averaged set of decoded LLRs.

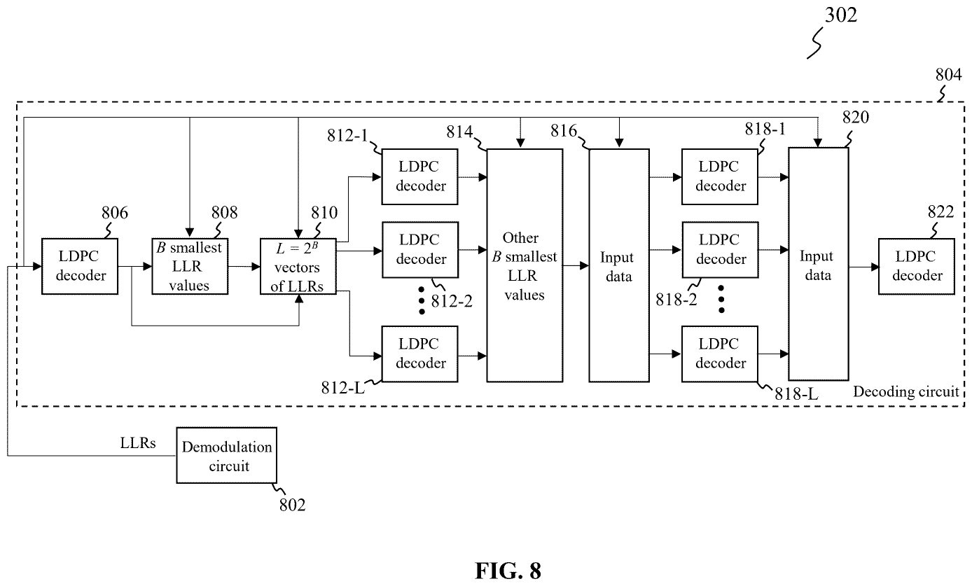

FIG. 8 shows a block diagram of the processor 302 included in the decoding apparatus 300 in accordance with one example embodiment. More specifically, in the embodiment shown in FIG. 8, the processor 302 is assumed to perform LDPC decoding. The processor 302 comprises a demodulation circuit 802 and a decoding circuit 804. The demodulation circuit 802 is configured to receive a modulated signal carrying a set of bits encoded with an LDPC code and demodulate it to obtain soft bit decisions in the form of LLRs which are real numbers. These LLRs obtained after demodulation are herein referred to as demodulated LLRs. The demodulated LLRs are then fed to the decoding circuit 804.

In the decoding circuit 804, an LDPC decoder 806 receives the demodulated LLRs and uses them to obtain decoded LLRs. The decoded LLRs are then fed to a unit 808 together with the demodulated LLRs. The unit 808 is configured to use both types of LLRs to find those B bit positions which should be set to the maximum possible absolute LLR value (i.e., saturated) in the same or similar manner as discussed above with reference to FIGS. 2A-2D. Once, the B bit positions are found and saturated, they are provided to a unit 810 together with the demodulated LLRs and the decoded LLRs. The unit 810 is configured to form the first 2^{B} vectors of LLRs, as indicated above. It should be noted that the joint operation of the LDPC decoder 806 and the units 808, 810 implements the input decoding stage of the multi-stage decoding algorithm.

The first 2^{B} vectors of LLRs are then processed by LDPC decoders 812-1, 812-2, . . . , 812-L, respectively. The output data of the LDPC decoders 812-1, 812-2, . . . , 812-L (i.e., the individual sets of decoded LLRs for the first 2^{B} vectors of LLRs) are then averaged by a unit 814 to obtain the first averaged set of decoded LLRs and find other B bit positions to be saturated. Said “other B bit positions” refer to those bit positions which have not been used at the input decoding stage. The other B bit positions and the demodulated LLRs are further fed to a next unit 816. It should be noted that the joint operation of the LDPC decoders 812-1, 812-2, . . . , 812-L and the units 814, 816 implements the first intermediate decoding stage of the multi-stage decoding algorithm. The unit 816 uses the received data to form the input data for the second intermediate decoding stage (i.e., the second 2^{B} vectors of LLRs).

The second intermediate decoding stage is implemented by the joint operation of LDPC decoders 818-1, 818-2, . . . , 818-L and a unit 820. More specifically, each of the LDPC decoders 818-1, 818-2, . . . , 818-L receives one of the second 2^{B} vectors of LLRs from the unit 816 and uses it to obtain an individual set of decoded LLRs for that 2^{B} vector of LLRs. The unit 820 averages the individual sets of decoded LLRs to obtain the second averaged set of decoded LLRs.

The output decoding stage of the multi-stage decoding algorithm is implemented by the operation of an LDPC decoder 822 that uses the set of demodulated LLRs and the second averaged set of decoded LLRs from the unit 820 to finally decode the set of bits.

It should be noted that, depending on the parameters (e.g., coding rate, code block length, etc.) of the code by which the initial set of bits has been encoded, there may be more than two intermediate decoding stages performed on the receiving side. With reference to FIG. 8, there may be an additional intermediate decoding stage between the first intermediate decoding stage (implemented by the joint operation of the LDPC decoders 812-1, 812-2, . . . , 812-L and the units 814, 816) and the second intermediate decoding stage (implemented by the joint operation of LDPC decoders 818-1, 818-2, . . . , 818-L and a unit 820). Said additional intermediate decoding stage may be similar to the first intermediate decoding stage in design and functionality, i.e., may use the output of the unit 816 as input data to obtain an additional averaged set of decoded LLRs based on the second 2^{B} vectors of LLRs and find an additional subset of B bit positions therein (which does not overlap with the first and second subsets of B bit positions). Then, said additional intermediate decoding stage may form third 2^{B} vectors of LLRs for the second intermediate decoding stage based on the set of demodulated LLRs, the additional averaged set of decoded LLRs and the additional subset of B bit positions. Further, the second intermediate decoding stage may use the third 2^{B} vectors of LLRs to properly form the input data for the output decoding stage.

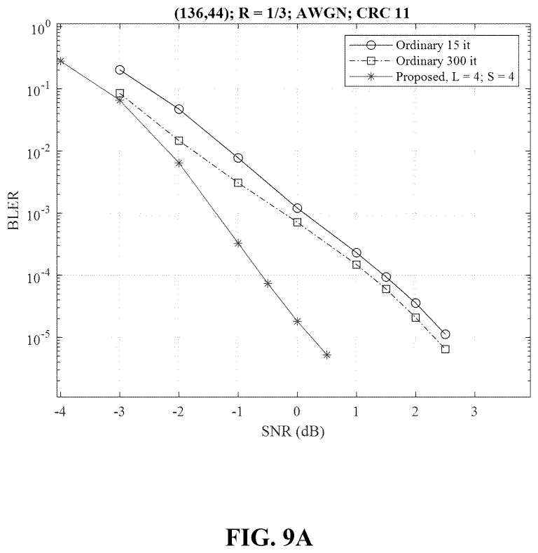

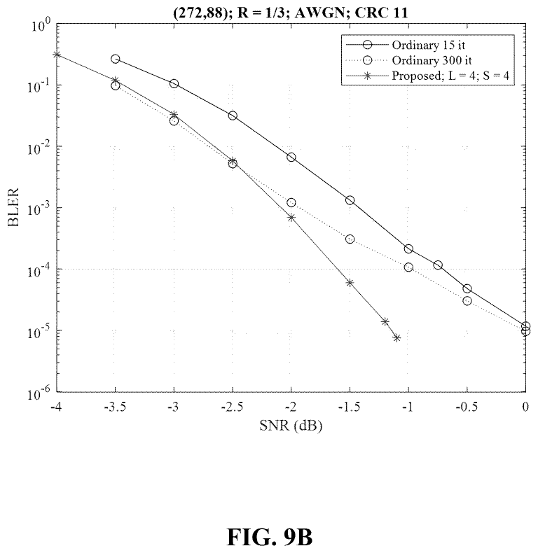

FIGS. 9A and 9B show a BLER versus a Signal-to-Noise Ratio (SNR), as obtained by using a conventional decoding method and the method 400 for two different LDPC codes. More specifically, the curves shown in FIG. 9A are obtained for the LDPC code having K=44 information bits and a code rate of R=1/3, while the curves shown in FIG. 9B are obtained for the LDPC code having K=88 information bits and a code rate of R=1/3. The conventional (or ordinary) decoding method refers to the one performed by the LDPC decoder 100 but without using the saturation approach proposed by P. Schlaefer, et. al., in the above-cited document. In FIG. 9A, the solid curves with circular points are obtained by using 15 iterations in the conventional decoding method, the dash-dotted curves with square points are obtained by using 300 iterations in the conventional decoding method, and the solid curves with asterisks are obtained by using L=4 vectors of LLRs and four intermediate stages (each with max 15 iterations) in the method 400. In FIG. 9B, the solid curves with circular points are obtained by using 15 iterations in the conventional decoding method, the dotted curves with circular points are obtained by using 300 iterations in the conventional decoding method, and the solid curves with asterisks are obtained by using L=4 vectors of LLRs and four intermediate stages (each with max 15 iterations) in the method 400. As follows from FIG. 9A, the method 400 has a gain of 2.3 dB at BLER=10⁻⁵. The gain provided by the method 400 is also clearly visible in FIG. 9B.

It should be noted that each step or operation of the method 400 and the sub-step sequences 500-700, or any combinations of the steps or operations, can be implemented by various means, such as hardware, firmware, and/or software. As an example, one or more of the steps or operations described above can be embodied by processor executable instructions, data structures, program modules, and other suitable data representations. Furthermore, the processor-executable instructions which embody the steps or operations described above can be stored on a corresponding data carrier and executed by the processor 302. This data carrier can be implemented as any computer-readable storage medium configured to be readable by said at least one processor to execute the processor executable instructions. Such computer-readable storage media can include both volatile and nonvolatile media, removable and non-removable media. By way of example, and not limitation, the computer-readable media comprise media implemented in any method or technology suitable for storing information. In more detail, the practical examples of the computer-readable media include, but are not limited to information-delivery media, RAM, ROM, EEPROM, flash memory or other memory technology, CD-ROM, digital versatile discs (DVD), holographic media or other optical disc storage, magnetic tape, magnetic cassettes, magnetic disk storage, and other magnetic storage devices.

Although the example embodiments of the present disclosure are described herein, it should be noted that any various changes and modifications could be made in the embodiments of the present disclosure, without departing from the scope of legal protection which is defined by the appended claims. In the appended claims, the word “comprising” does not exclude other elements or operations, and the indefinite article “a” or “an” does not exclude a plurality. The mere fact that certain measures are recited in mutually different dependent claims does not indicate that a combination of these measures cannot be used to advantage.

1. A decoding apparatus in a wireless communication network, comprising:
at least one processor; and
at least one memory storing instructions that, when executed by the at least one processor, cause the decoding apparatus at least to:
receive a modulated signal comprising a set of bits encoded with a linear error-correcting block code, each bit of the set of bits having a bit position;
obtain a set of demodulated Log Likelihood Ratios (LLRs) for the set of bits by demodulating the modulated signal; and
decode the set of bits by using a multi-stage decoding algorithm comprising an input decoding stage, a first intermediate decoding stage, a second intermediate decoding stage and an output decoding stage;
wherein the decoding apparatus is caused, at the input decoding stage, to: (i) obtain a set of decoded LLRs based on the set of demodulated LLRs; (ii) find a first subset of B bit positions each associated with a first smallest absolute LLR value in the set of decoded LLRs, where B is a natural number; (iii) instead of the first smallest absolute LLR value, assign a maximum possible absolute LLR value to each bit position of the first subset of B bit positions; and (iv) form first 2^{B} vectors of LLRs based on the set of demodulated LLRs, the set of decoded LLRs and the first subset of B bit positions;
wherein the decoding apparatus is caused, at the first intermediate decoding stage, to: (v) decode each of the first 2^{B} vectors of LLRs in parallel, thereby obtaining an individual set of decoded LLRs for each of the first 2^{B} vectors of LLRs; (vi) obtain a first averaged set of decoded LLRs by averaging the individual sets of decoded LLRs obtained in operation (v); (vii) find a second subset of B bit positions each associated with a second smallest absolute LLR value in the first averaged set of decoded LLRs, the second subset of B bit positions and the first subset of B bit positions being non-overlapping; (viii) instead of the second smallest absolute LLR value, assign the maximum possible absolute LLR value to each bit position of the second subset of B bit positions; (ix) form second 2^{B} vectors of LLRs based on the set of demodulated LLRs, the first averaged set of decoded LLRs and the second subset of B bit positions;
wherein the decoding apparatus is caused, at the second decoding stage, to: (x) decode each of the second 2^{B} vectors of LLRs in parallel, thereby obtaining an individual set of decoded LLRs for each of the second 2^{B} vectors of LLRs; and (xi) obtain a second averaged set of decoded LLRs by averaging the individual sets of decoded LLRs obtained in operation (x); and
wherein the decoding apparatus is caused, at the output decoding stage, to (xii) decode the set of bits based on the set of demodulated LLRs and the second averaged set of decoded LLRs.

2. The decoding apparatus of claim 1, wherein the linear error-correcting block code is a Low-Density Parity-Check (LDPC) code or a polar code, and wherein the multi-stage decoding algorithm is an LDPC decoding algorithm or a polar code decoding algorithm, respectively.

3. The decoding apparatus of claim 2, wherein the LDPC decoding algorithm is a min-sum LDPC decoding algorithm or a sum-product LDPC decoding algorithm.

4. The decoding apparatus of claim 1, wherein the decoding apparatus is further caused, in operation (ix), to calculate a weighted sum of the set of demodulated LLRs and the first averaged set of decoded LLRs, and to form the second 2^{B} vectors of LLRs based on the weighted sum of the set of demodulated LLRs and the first averaged set of decoded LLRs.

5. The decoding apparatus of claim 4, wherein the linear error-correcting block code has a block length and a code rate, and wherein the decoding apparatus is further caused to calculate the weighted sum of the set of demodulated LLRs and the first averaged set of decoded LLRs based on the block length and the code rate.

6. The decoding apparatus of claim 1, wherein the decoding apparatus is further caused, in operations (i), (vi) and (x), to check whether there is at least one bit error in the set of decoded LLRs, the first averaged set of decoded LLRs and the second averaged set of decoded LLRs, respectively, by using a Cyclic Redundancy Check (CRC) technique.

7. A decoding method in a wireless communication network, comprising:
receiving a modulated signal comprising a set of bits encoded with a linear error-correcting block code, each bit of the set of bits having a bit position;
obtaining a set of demodulated Log Likelihood Ratios (LLRs) for the set of bits by demodulating the modulated signal; and
decoding the set of bits by using a multi-stage decoding algorithm comprising an input decoding stage, a first intermediate decoding stage, a second intermediate decoding stage and an output decoding stage;
wherein the input decoding stage comprises: (i) obtaining a set of decoded LLRs based on the set of demodulated LLRs; (ii) finding a first subset of B bit positions each associated with a first smallest absolute LLR value in the set of decoded LLRs, where B is a natural number; (iii) instead of the first smallest absolute LLR value, assigning a maximum possible absolute LLR value to each bit position of the first subset of B bit positions; and (iv) forming first 2^{B} vectors of LLRs based on the set of demodulated LLRs, the set of decoded LLRs and the first subset of B bit positions;
wherein the first intermediate decoding stage comprises: (v) decoding each of the first 2^{B} vectors of LLRs in parallel, thereby obtaining an individual set of decoded LLRs for each of the first 2^{B} vectors of LLRs; (vi) obtaining a first averaged set of decoded LLRs by averaging the individual sets of decoded LLRs obtained in step (v); (vii) finding a second subset of B bit positions each associated with a second smallest absolute LLR value in the first averaged set of decoded LLRs, the second subset of B bit positions and the first subset of B bit positions being non-overlapping; (viii) instead of the second smallest absolute LLR value, assigning the maximum possible absolute LLR value to each bit position of the second subset of B bit positions; (ix) forming second 2^{B} vectors of LLRs based on the set of demodulated LLRs, the first averaged set of decoded LLRs and the second subset of B bit positions;
wherein the second decoding stage comprises: (x) decoding each of the second 2^{B} vectors of LLRs in parallel, thereby obtaining an individual set of decoded LLRs for each of the second 2^{B} vectors of LLRs; and (xi) obtaining a second averaged set of decoded LLRs by averaging the individual sets of decoded LLRs obtained in step (x); and
wherein the output decoding stage comprises (xii) decoding the set of bits based on the set of demodulated LLRs and the second averaged set of decoded LLRs.

8. The method of claim 7, wherein the linear error-correcting block code is a Low-Density Parity-Check (LDPC) code or a polar code, and wherein the multi-stage decoding algorithm is an LDPC decoding algorithm or a polar code decoding algorithm, respectively.

9. The method of claim 8, wherein the LDPC decoding algorithm is a min-sum LDPC decoding algorithm or a sum-product LDPC decoding algorithm.

10. The method of claim 7, wherein step (ix) is performed by calculating a weighted sum of the set of demodulated LLRs and the first averaged set of decoded LLRs and forming the second 2^{B} vectors of LLRs based on the weighted sum of the set of demodulated LLRs and the first averaged set of decoded LLRs.

11. The method of claim 10, wherein the linear error-correcting block code has a block length and a code rate, and wherein the weighted sum of the set of demodulated LLRs and the first averaged set of decoded LLRs is calculated based on the block length and the code rate.

12. The method of claim 7, further comprising, in steps (i), (vi) and (x), checking whether there is at least one bit error in the set of decoded LLRs, the first averaged set of decoded LLRs and the second averaged set of decoded LLRs, respectively, by using a Cyclic Redundancy Check (CRC) technique.

13. A computer program product comprising a computer-readable storage medium, wherein the computer-readable storage medium stores a computer code which, when executed by at least one processor, causes the at least one processor to:
receive a modulated signal comprising a set of bits encoded with a linear error-correcting block code, each bit of the set of bits having a bit position;
obtain a set of demodulated Log Likelihood Ratios (LLRs) for the set of bits by demodulating the modulated signal; and
decode the set of bits by using a multi-stage decoding algorithm comprising an input decoding stage, a first intermediate decoding stage, a second intermediate decoding stage and an output decoding stage;
wherein the at least one processor is caused, at the input decoding stage, to: (i) obtain a set of decoded LLRs based on the set of demodulated LLRs; (ii) find a first subset of B bit positions each associated with a first smallest absolute LLR value in the set of decoded LLRs, where B is a natural number; (iii) instead of the first smallest absolute LLR value, assign a maximum possible absolute LLR value to each bit position of the first subset of B bit positions; and (iv) form first 2^{B} vectors of LLRs based on the set of demodulated LLRs, the set of decoded LLRs and the first subset of B bit positions;
wherein the at least one processor is caused, at the first intermediate decoding stage, to: (v) decode each of the first 2^{B} vectors of LLRs in parallel, thereby obtaining an individual set of decoded LLRs for each of the first 2^{B} vectors of LLRs; (vi) obtain a first averaged set of decoded LLRs by averaging the individual sets of decoded LLRs obtained in operation (v); (vii) find a second subset of B bit positions each associated with a second smallest absolute LLR value in the first averaged set of decoded LLRs, the second subset of B bit positions and the first subset of B bit positions being non-overlapping; (viii) instead of the second smallest absolute LLR value, assign the maximum possible absolute LLR value to each bit position of the second subset of B bit positions; (ix) form second 2^{B} vectors of LLRs based on the set of demodulated LLRs, the first averaged set of decoded LLRs and the second subset of B bit positions;
wherein the at least one processor is caused, at the second decoding stage, to: (x) decode each of the second 2^{B} vectors of LLRs in parallel, thereby obtaining an individual set of decoded LLRs for each of the second 2^{B} vectors of LLRs; and (xi) obtain a second averaged set of decoded LLRs by averaging the individual sets of decoded LLRs obtained in operation (x); and
wherein the at least one processor is caused, at the output decoding stage, to (xii) decode the set of bits based on the set of demodulated LLRs and the second averaged set of decoded LLRs.

14. The computer program product of claim 13, wherein the linear error-correcting block code is a Low-Density Parity-Check (LDPC) code or a polar code, and wherein the multi-stage decoding algorithm is an LDPC decoding algorithm or a polar code decoding algorithm, respectively.

15. The computer program product of claim 13, wherein the LDPC decoding algorithm is a min-sum LDPC decoding algorithm or a sum-product LDPC decoding algorithm.

16. The computer program product of claim 13, wherein the at least one processor is further caused, in operation (ix), to calculate a weighted sum of the set of demodulated LLRs and the first averaged set of decoded LLRs, and to form the second 2^{B} vectors of LLRs based on the weighted sum of the set of demodulated LLRs and the first averaged set of decoded LLRs.

17. The computer program product of claim 16, wherein the linear error-correcting block code has a block length and a code rate, and wherein the at least one processor is further caused to calculate the weighted sum of the set of demodulated LLRs and the first averaged set of decoded LLRs based on the block length and the code rate.

18. The computer program product of claim 13, wherein the at least one processor is further caused, in operations (i), (vi) and (x), to check whether there is at least one bit error in the set of decoded LLRs, the first averaged set of decoded LLRs and the second averaged set of decoded LLRs, respectively, by using a Cyclic Redundancy Check (CRC) technique.
